(19) United States
(12) Patent Application Publication
(10) Pub. No.: US 2026/0123310 A1
(43) Pub. Date: Apr. 30, 2026

(54) DIRECTIONAL ANGLED ETCH FOR HARDMASK OPENING AND LWR IMPROVEMENT

(71) Applicant: Applied Materials, Inc., Santa Clara, CA (US)

(72) Inventors: Chen-Chih Hsu, Gloucester, MA (US); Yung-Chen Lin, Westwood, MA (US); Shurong Liang, Lynnfield, MA (US); Steven Sherman, Newton, MA (US)

(73) Assignee: Applied Materials, Inc., Santa Clara, CA (US)

(21) Appl. No.: 18/925,805

(22) Filed: Oct. 24, 2024

(51) Int. Cl. H01L 21/3065; H01L 21/027; H01L 21/033; H01L 21/67

(52) U.S. Cl. CPC H10P 50/242; H10P 72/0421; H10P 76/2041; H10P 76/405; H10P 76/4085

(57) ABSTRACT

Disclosed herein are approaches for directional angled etching to form hardmask openings and to reduce line-width-roughness (LWR) of patterning lines. In one approach, a method may include forming a plurality of mask lines over a stack of layers, wherein each of the plurality of mask lines includes a first sidewall and a second sidewall, and wherein a surface defect is present along the first sidewall or the second sidewall. The method may further include removing the surface defect by delivering a reactive plasma beam to the plurality of mask lines at a non-zero angle relative to a perpendicular to a plane defined by an upper surface of the plurality of mask lines.

### FIELD OF THE DISCLOSURE

The present disclosure relates to semiconductor device patterning and, more particularly, to directional angled etching for formation of hardmask openings and line-width-roughness reduction.

### BACKGROUND OF THE DISCLOSURE

Blocking and patterning features are widely used for creating 2D and 3D patterns in microelectronic devices. Lithography is one such approach, and involves spin-on deposition of an underlayer and a film (photoresist) over the underlayer. These spin-on films may include some chemical additives/aids for dose reduction. The process may continue with irradiation of the film with a selected pattern by an energy source (e.g., exposure), and removal (e.g., etch) of exposed or non-exposed regions of the film by dissolving in a solvent. A bake may be carried out to drive off remaining solvent. Spin-on underlayer solutions have some drawbacks, however, particularly with extreme ultraviolet (EUV) lithography operations for smaller pitch features. For example, drawbacks may include composition uniformity and poor adhesion to the photoresist.

Several properties are important in lithography processes, such as sensitivity, resolution, line-edge roughness (LER), line-width-roughness (LWR), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films, while thinner films increase the efficiency of the lithographic process. LER and LWR may be transferred to one or more other layers of the device stack, which may be problematic. However, removing these LER and LWR defects after formation is challenging.

It is with respect to these and other considerations that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a plurality of mask lines over a stack of layers, wherein each of the plurality of mask lines includes a first sidewall and a second sidewall, and wherein a surface defect is present along the first sidewall or the second sidewall. The method may further include removing the surface defect by delivering a reactive plasma beam to the plurality of mask lines at a non-zero angle relative to a perpendicular to a plane defined by an upper surface of the plurality of mask lines.

In another aspect, a method for minimizing surface defects present along a plurality of patterning features may include forming the plurality of patterning lines over a stack of layers of a semiconductor device, wherein each of the plurality of patterning lines includes a first sidewall and a second sidewall connected by an upper surface, and wherein a surface defect is present along at least one of the first sidewall and the second sidewall. The method may further include removing the surface defect by delivering a reactive plasma beam to the plurality of patterning lines at a non-zero angle relative to a perpendicular to a plane defined by the upper surface.

In yet another aspect, a processing apparatus may include a chamber operable to contain a plasma within a chamber volume, the chamber defined by a plurality of sidewalls, and a plate assembly proximate the chamber, wherein ions are extracted through a plurality of apertures of the plate assembly and delivered to a semiconductor device as a reactive plasma beam oriented at a non-zero angle relative to a perpendicular extending from an upper surface of a stack of layers of the semiconductor device. The ions are operable to remove a surface defect present along a sidewall of a plurality of patterning lines formed over the stack of layers of the semiconductor device.

### BRIEF DESCRIPTION OF THE DRAWINGS

The accompanying drawings illustrate exemplary approaches of the disclosure, including the practical application of the principles thereof, as follows:

FIG. 1A is a side cross-sectional view of a stack of layers of a semiconductor device including a plurality of patterning lines, according to embodiments of the present disclosure;

FIG. 1B is a top view of a stack of layers of a semiconductor device including a plurality of patterning lines, according to embodiments of the present disclosure;

FIG. 2A is a top view of a stack of layers of a semiconductor device including a plurality of patterning lines during an etch process, according to embodiments of the present disclosure;

FIG. 2B is a side cross-sectional view of a stack of layers of a semiconductor device including a plurality of patterning lines during an etch process, according to embodiments of the present disclosure;

FIG. 3 is a top view of a stack of layers of a semiconductor device including a plurality of patterning lines following an etch process to remove a plurality of defects, according to embodiments of the present disclosure;

FIG. 4A is a side cross-sectional view of a stack of layers of a semiconductor device including a plurality of patterning lines, according to embodiments of the present disclosure;

FIG. 4B is a top view of a stack of layers of a semiconductor device including a plurality of patterning lines, according to embodiments of the present disclosure;

FIG. 5A is a top view of a stack of layers of a semiconductor device including a plurality of patterning lines during an etch process, according to embodiments of the present disclosure;

FIG. 5B is a side cross-sectional view of a stack of layers of a semiconductor device including a plurality of patterning lines during an etch process, according to embodiments of the present disclosure;

FIG. 6 is a side cross-sectional view of a stack of layers of a semiconductor device following an etch process, according to embodiments of the present disclosure;

FIG. 7 is a side cross-sectional view of a stack of layers of a semiconductor device following an etch process, according to embodiments of the present disclosure;

FIG. 8 shows a semiconductor processing apparatus according to embodiments of the disclosure; and

FIG. 9 is a side view of a plasma processing chamber according to one or more embodiments.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### DETAILED DESCRIPTION

Methods and systems in accordance with the present disclosure will now be described more fully hereinafter with reference to the accompanying drawings, where various embodiments are shown. The methods and systems may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously reduce line/space LWR/LER of a plurality of patterning features, such as EUV lines, which is beyond capabilities of prior art lithography tools. Using a directional angled etch reduces low, middle, and high-frequency roughness dramatically, and allows achievement of close to 1nm LWR and < 1nm LER by EUV single print + directional etch process. The directional angled etch can also reduce a sidewall roughness of a hardmask opening, while permitting simultaneous etching down into the device stack. Furthermore, etch chemistries can be optimized to control the selectivity of an EUV underlayer during the directional angled etch. Using the approaches of the present disclosure enables poly gate patterning with a single print to have tight channel length (very low LWR), which is essential for small CD and small pitch to reduce process variation.

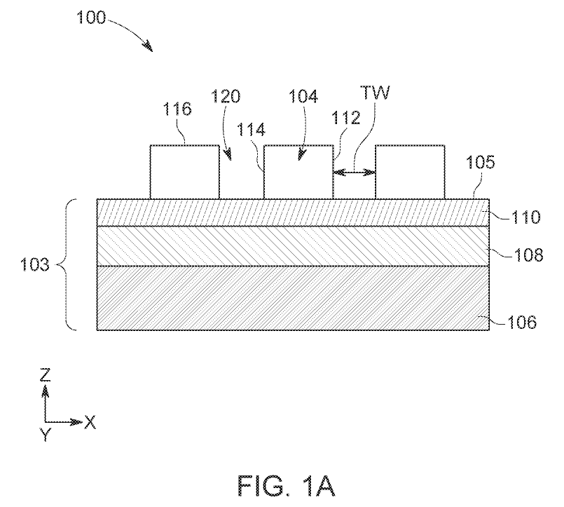

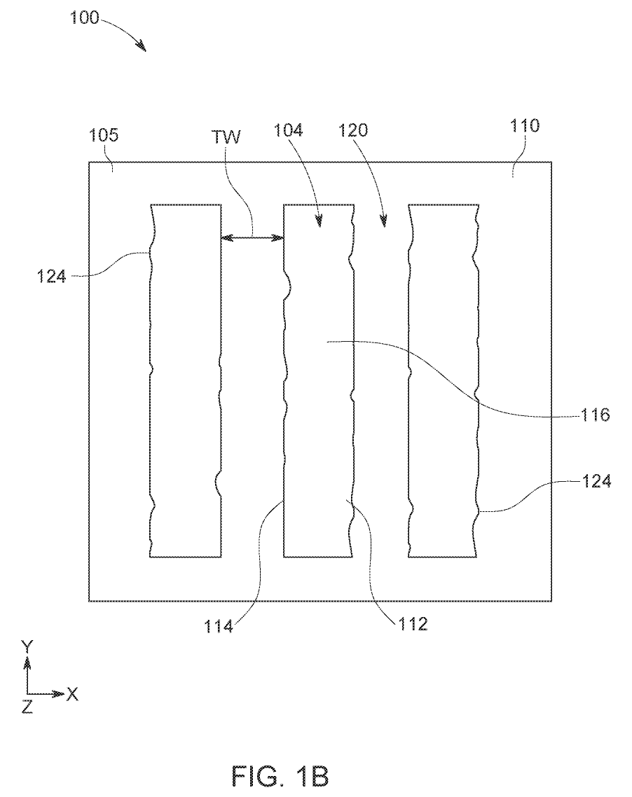

FIG. 1A depicts a portion of a semiconductor device (hereinafter “device”) 100, according to one or more embodiments. The device 100 may include a stack of layers 103, and a plurality of patterning features or lines 104 formed atop an upper surface 105 of the stack of layers 103. Although non-limiting, the stack of layers 103 may include a first underlayer 106, a film layer 108 over the first underlayer 106, and a second underlayer 110 over the film layer 108. Although non-limiting, the first underlayer 106 may be a silicon containing base hardmask (e.g., aSi, SiC, SiB, SiO2, SiN, SiON etc.), the film layer 108 may be a carbon film (e.g., APF, SOH, ACL etc.), and the second underlayer 110 may be a carbon, organic/inorganic underlayer for adhesion and dose reduction. In other embodiments, second underlayer 110 may be an amorphous silicon (aSi). Although non-limiting, the second underlayer 110 may be approximately 5-10nm thick (e.g., in the z-direction) in some embodiments. The stack of layers 103 may include additional layers not shown.

In some embodiments, the plurality of patterning lines 104 are formed from a photoresist layer into a desired pattern and shape. For example, each of the plurality of patterning lines 104 may include a first sidewall 112 opposite a second sidewall 114, and an upper surface 116 extending between the first and second sidewalls 112, 114. The plurality of patterning lines 104 may be defined by a plurality of openings or trenches 120 formed selective to the upper surface 105 of the stack of layers 103. The trenches 120 may have a trench width (TW) extending in the x-direction, between the first sidewall 112 and the second sidewall 114 of adjacent patterning lines 104. In the embodiment shown, TW is substantially the same for each of the trenches 120 of the device 100.

In the embodiment shown, the plurality of patterning lines 104 are formed from a metal-oxide resist (MOR). In another embodiment, the plurality of patterning lines 104 are formed from a chemically amplified resist (CAR). In the case of a CAR, the film layer 108 may not be present. Instead, the second underlayer 110 may be formed directly atop the first underlayer 106.

As better shown in the top view of FIG. 1B, one or more surface defects 124 may be present along at least one of the first sidewall 112 and the second sidewall 114 of the patterning lines 104. The surface defects 124 may be areas of roughness, e.g., areas containing unacceptable protrusions and/or indentations along the surfaces of the patterning lines 104 after formation. The surface defects 124 can take on any variety of shapes and sizes.

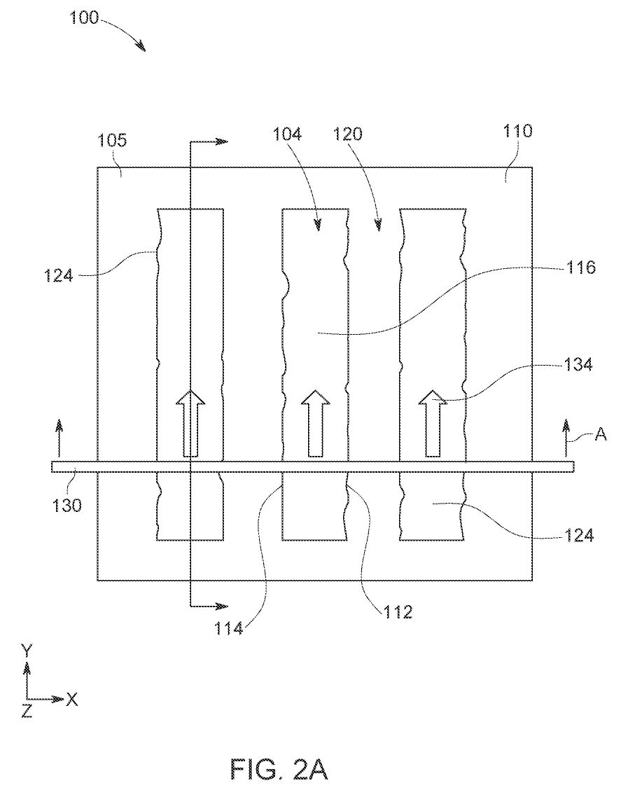

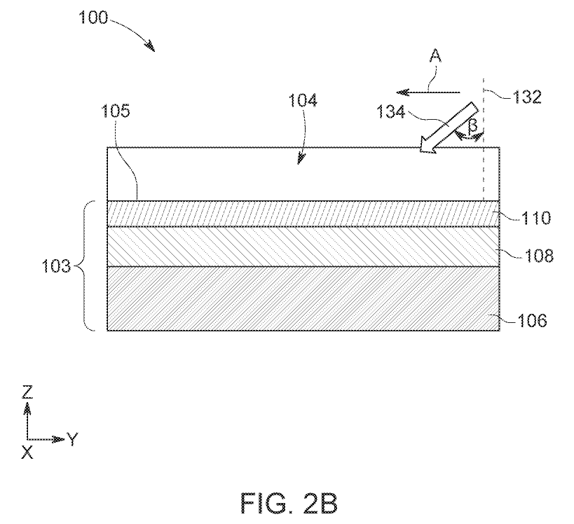

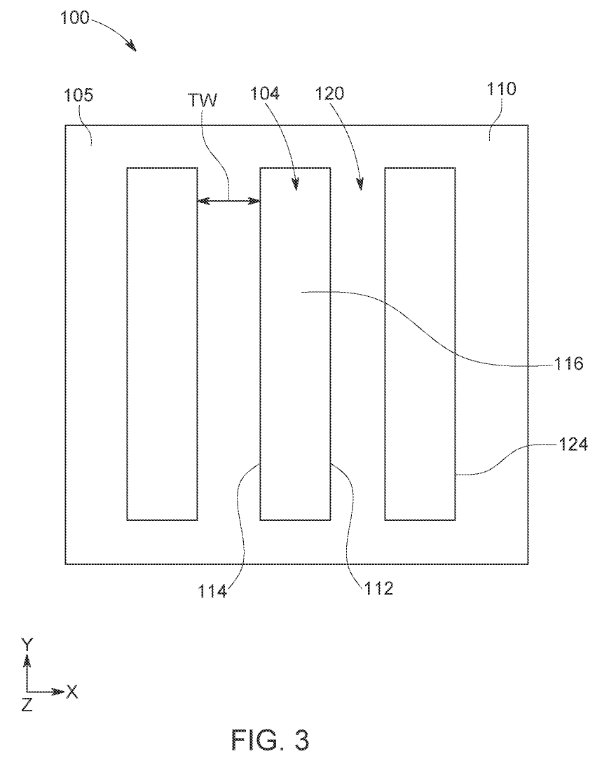

To remove these surface defects 124, as shown in FIGS. 2A – 2B, a reactive plasma beam 130 may be delivered to the plurality of patterning lines 104 at a non-zero angle (β) relative to a perpendicular 132 (FIG. 2B) to a plane defined by the upper surface of the stack of layers 103. That is, angled ions 134 from the reactive plasma beam 130 may etch the surface defects 124 as the reactive plasma beam 130 is moving/scanning in the y-direction, as shown by arrow ‘A’. Although non-limiting, the angled ions 134 may include an inert gas species suitable for carbon films, such as helium (He), argon (Ar), nitrogen (N2), etc. Other etch chemistries may be used in alternative embodiments. For example, dissociation ions such as Ar+, H+, CH+, CF+, Cl+, Br+ may be used to reduce L/S roughness. Following the etch process, the surface defects 124 may be eliminated, or substantially reduced, as demonstrated in FIG. 3. Advantageously, the TW of each trench 120 has not increased as a result of the removal process.

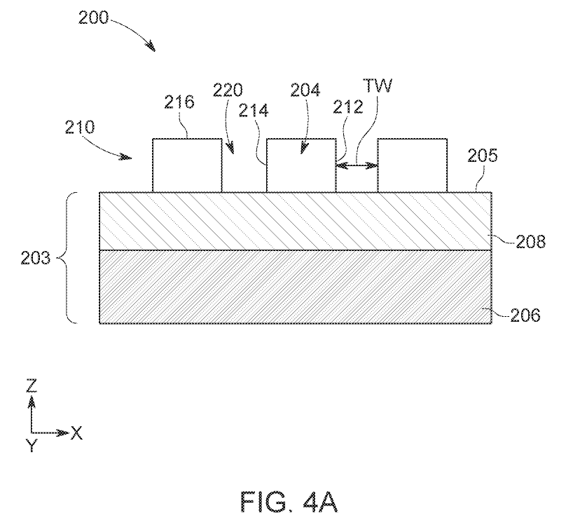

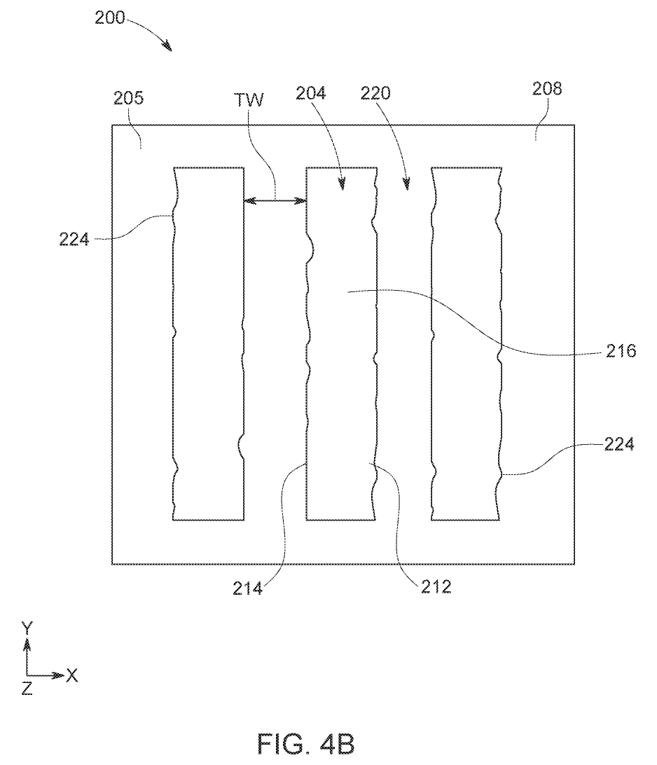

FIG. 4A depicts a portion of a semiconductor device (hereinafter “device”) 200, according to one or more embodiments. The device 200 may include a stack of layers 203, and a plurality of mask features or mask lines 204 formed atop an upper surface 205 of the stack of layers 203. Although non-limiting, the stack of layers 203 may include an underlayer 206, a first hardmask layer 208 over the underlayer 206, and a second hardmask layer 210 over the first hardmask layer 208. In various embodiments, the first hardmask layer 208 may include a carbon, Si-containing film, or a metal oxide, while the second hardmask layer 210 may include a resist material, carbon, Si-containing hardmask, or a metal oxide.

In some embodiments, the plurality of mask lines 204 are formed from the second hardmask layer 210 into a desired pattern and shape. For example, each of the plurality of mask lines 204 may include a first sidewall 212 opposite a second sidewall 214, and an upper surface 216 extending between the first and second sidewalls 212, 214. The plurality of mask lines 204 may be defined by a plurality of openings or trenches 220 formed selective to the upper surface 205 of the stack of layers 203. The trenches 220 may have a trench width (TW) extending in the x-direction, between the first sidewall 212 and the second sidewall 214 of adjacent mask lines 204. In the embodiment shown, TW is substantially the same for each of the trenches 220.

As better shown in the top view of FIG. 4B, one or more surface defects 224 may be present along at least one of the first sidewall 212 and the second sidewall 214 of the mask lines 204. The surface defects 224 may be areas of roughness, e.g., areas containing unacceptable protrusions and/or indentations along the surfaces of the mask lines 204 after formation. The surface defects 224 can take on any variety of shapes and sizes.

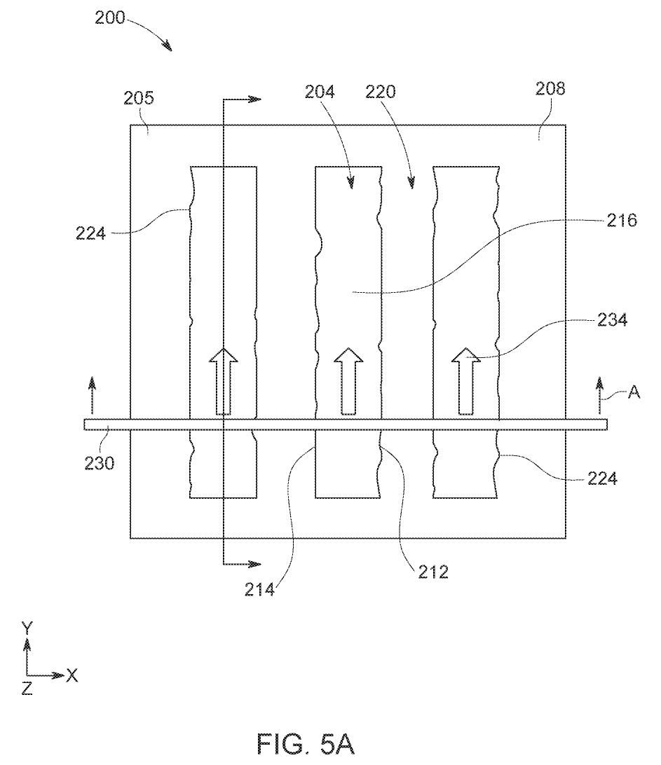

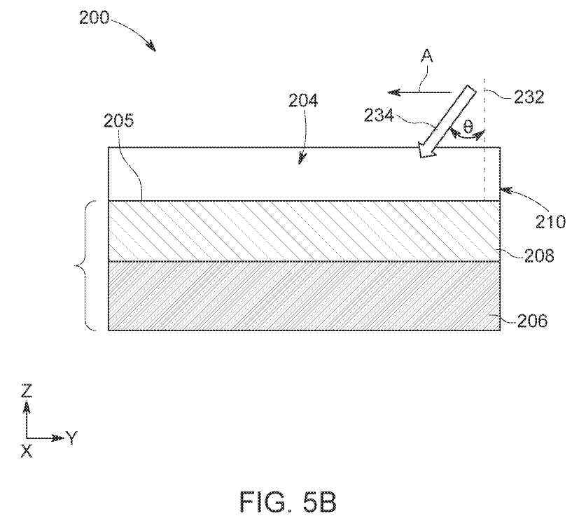

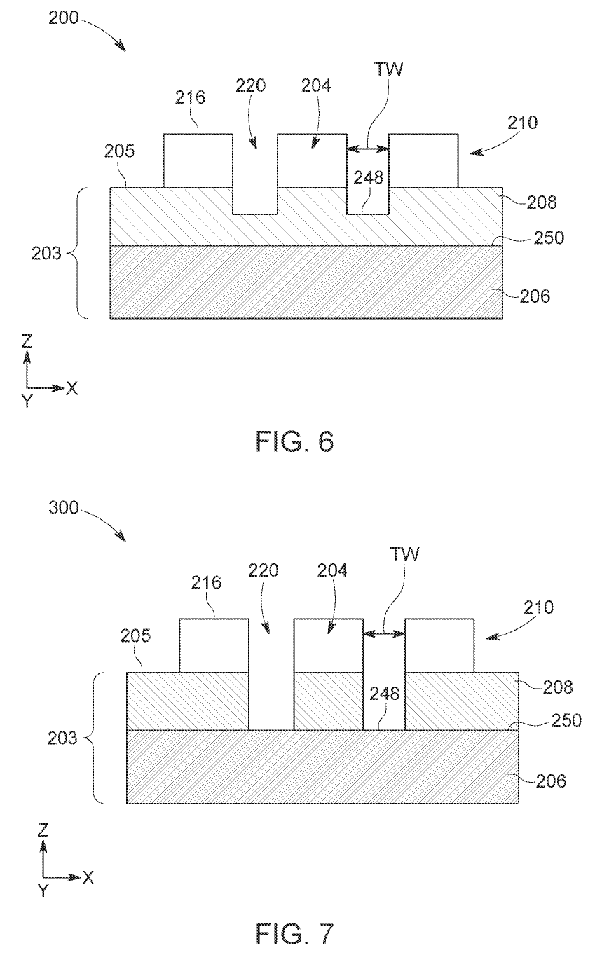

To remove these surface defects 224, as shown in FIGS. 5A – 5B, a reactive plasma beam 230 may be delivered to the plurality of mask lines 204 at a non-zero angle (θ) relative to a perpendicular 232 (FIG. 5B) to a plane defined by the upper surface of the stack of layers 203. That is, angled ions 234 from the reactive plasma beam 230 may etch the surface defects 224 as the reactive plasma beam 230 is moving/scanning in the y-direction, as shown by arrow ‘A’. Although non-limiting, the angled ions 234 may include an inert gas species suitable for carbon films, such as helium (He), argon (Ar), nitrogen (N2), etc. Other etch chemistries may be used in alternative embodiments. For example, a fluorine-based chemistry (e.g., CF4, CHF3, CH2F2, CH3F, SF6, NF3, C4F6, C4F8, etc.) or a halogen-based chemistry (e.g., Cl2, HBR) may be used to remove the surface defects 224 while also simultaneously recessing the trenches 220 further into the first hardmask layer 208, as shown in FIG. 6. That is, a bottom surface 248 of the trenches 220 is formed into the first hardmask layer 208, i.e., below a plane defined by the upper surface 205 of the stack of layers 203 and above a plane defined by an upper surface 250 of the underlayer 206. Because the first hardmask layer 208 is being recessed as the surface defects 224 are being removed, the non-zero angle (θ) may be relatively smaller, e.g., between 10-45°, than the non-zero angle (β) shown in FIG. 2B and described above. Advantageously, the TW of each trench 220 has not increased as a result of the defect removal and trench deepening processes.

In some embodiments, O2, H2 or N2 chemistries may be the used. In some embodiments, fluorine radicals may react with the second hardmask layer 210 and/or the first hardmask layer 208 to form SiF4, which is volatile, and which therefore may be pumped out to avoid byproduct redeposition. In some embodiments, halogen radicals (e.g. Cl* and Br*) may be used. In some embodiments, dissociation ions, such as Ar+, H+, CH+, CF+, Cl+, Br+, may be used. In some embodiments, passivation may occur using carbon species or CHx radicals to form a deposition layer, which reduces CD loss.

FIG. 7 demonstrates an alternative embodiment of a device 300 in which the removal process continues, as described above with respect to device 200, until the trenches 220 continue to the upper surface 250 of the of the underlayer 206.

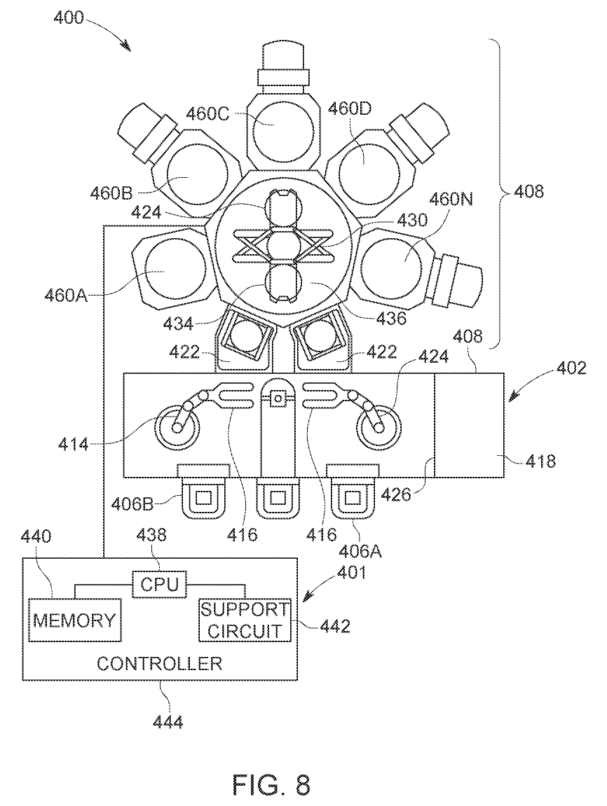

FIG. 8 is a schematic top plan view of an exemplary cluster processing system 400 that includes one or more of the processing chambers operable to form the devices 100, 200, and 300 described herein. In one embodiment, the cluster processing system 400 may be an integrated processing system commercially available from Applied Materials, Inc., located in Santa Clara, CA. It is contemplated that other processing systems (including those from other manufacturers) may be adapted to benefit from the disclosure.

The cluster processing system 400 may include a vacuum-tight processing platform 404, a factory interface 402, and a system controller 444. The platform 404 includes a plurality of processing chambers 460A – 460N and at least one load-lock chamber 422 that is coupled to a vacuum substrate transfer chamber 436. Two load lock chambers 422 are shown in FIG. 8. The factory interface 402 is coupled to the transfer chamber 436 by the load lock chambers 422.

In one embodiment, the factory interface 402 comprises at least one docking station 408 and at least one factory interface robot 414 to facilitate transfer of substrates. The docking station 408 is configured to accept one or more front opening unified pod (FOUP). The factory interface robot 414 having a blade 416 disposed on one end of the robot 414 is configured to transfer the substrate from the factory interface 402 to the processing platform 404 for processing through the load lock chambers 422. Optionally, one or more metrology stations 418 may be connected to a terminal 426 of the factory interface 402 to facilitate measurement of the substrate from the FOUPS 406A-B.

Each of the load lock chambers 422 have a first port coupled to the factory interface 402 and a second port coupled to the transfer chamber 436. The load lock chambers 422 are coupled to a pressure control system (not shown) which pumps down and vents the load lock chambers 422 to facilitate passing the substrate between the vacuum environment of the transfer chamber 436 and the substantially ambient (e.g., atmospheric) environment of the factory interface 402.

In one embodiment of the cluster processing system 400, the cluster processing system 400 may include one or more processing chambers 460A – 460N, which may include a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, curing chamber, lithographic exposure chamber, or other similar type of semiconductor processing chambers. More specifically, the etch chamber 460C may include an etch tool operable to perform an angled etch using a reactive plasma beam delivered at a non-zero angle to remove patterning defects and/or open hardmask layers of various devices, as described herein with respect to devices 100, 200, and 300.

The transfer chamber 436 has a vacuum robot 430 disposed therein. The vacuum robot 430 has a blade 434 capable of transferring substrates 424 among the load lock chambers 422, the metrology system 410 and the processing chambers 460A – 460N.

The system controller 444 is coupled to the cluster processing system 400. The system controller 444, which may include the computing device 401 or be included within the computing device 401, controls the operation of the cluster processing system 400 using a direct control of the processing chambers 460A – 460N of the cluster processing system 400. Alternatively, the system controller 444 may control the computers (or controllers) associated with the processing chambers 460A – 460N and the cluster processing system 400. In operation, the system controller 444 also enables data collection and feedback from the respective chambers to optimize performance of the cluster processing system 400.

The system controller 444, much like the computing device 401 described above, generally includes a central processing unit (CPU) 438, a memory 440, and support circuits 442. The CPU 438 may be one of any form of a general-purpose computer processor that can be used in an industrial setting. The support circuits 442 are conventionally coupled to the CPU 438 and may comprise cache, clock circuits, input/output subsystems, power supplies, and the like. The software routines transform the CPU 438 into a specific purpose computer (controller) 444. The software routines may also be stored and/or executed by a second controller (not shown) that is located remotely from the cluster processing system 400.

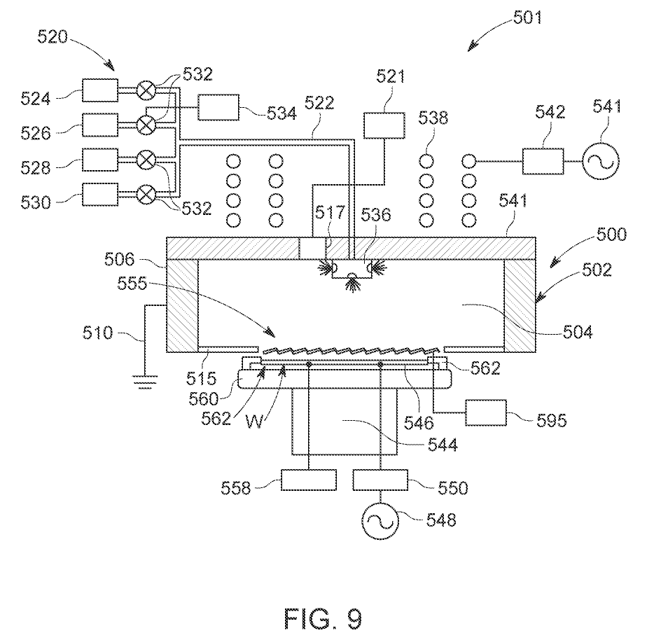

FIG. 9 is a schematic cross-sectional view of a processing apparatus 501 including an exemplary plasma processing chamber 500 suitable for performing a patterning process. One example of the plasma processing chamber 500 is a Centura® Sculpta® patterning chamber, available from Applied Materials, Inc., located in Santa Clara, CA. The plasma processing chamber 500 may correspond to one of the processing chambers 460A – 460N of the cluster processing system 400 described above. It is contemplated that other process chambers, including those from other manufactures, may be adapted to practice embodiments of the disclosure. It will be further contemplated that the components of the processing apparatus 501 are not necessarily to scale. The drawings are merely representations, not intended to portray specific parameters of the disclosure.

The plasma processing chamber 500 includes a chamber body 502 having a chamber volume 504 defined therein. The chamber body 502 has sidewalls 506, a first end wall 514, and a second end wall 515, wherein any of the sidewalls 506, the first end wall 514, or the second end wall 515 may be coupled to ground 510. Although non-limiting, the chamber body 502 may be cylindrical. In some embodiments, the sidewalls 506 may have a liner to protect the sidewalls 506 and extend the time between maintenance cycles of the plasma processing chamber 500. The chamber body 502 may support the first end wall 514, which encloses the chamber volume 504. The chamber body 502 may be fabricated from aluminum or other suitable materials. The dimensions of the chamber body 502 and related components of the plasma processing chamber 500 are not limited and generally are proportionally larger than the size of a substrate W to be processed therein. Although non-limiting, examples of substrate sizes include 166 mm diameter, 250 mm diameter, 300 mm diameter and 450 mm diameter, among others.

In some embodiments, a pumping port (not shown) may be formed through the sidewall 506 of the chamber body 505 and connected to the chamber volume 504, while a pumping device (not shown) may be coupled through the pumping port to the chamber volume 504 to evacuate and control the pressure therein. The pumping device may include one or more pumps and throttle valves.

A gas panel 520 may be coupled by a gas line 522 to the chamber body 505 to supply process gases into the chamber volume 504. The gas panel 520 may include one or more process gas sources 524, 526, 528, 530 and may additionally include inert gases, non-reactive gases, and reactive gases, if desired. Examples of process gases that may be provided by the gas panel 520 include, but are not limited to, hydrocarbon containing gas including methane (CH4), sulfur hexafluoride (SF6), silicon chloride (SiCl4), carbon tetrafluoride (CF4), hydrogen bromide (HBr), hydrocarbon containing gas, argon gas (Ar), chlorine (Cl2), nitrogen (N2), helium (He) and oxygen gas (O2). Additionally, process gases may include nitrogen, chlorine, fluorine, oxygen and hydrogen containing gases such as BCl3, C2F4, C4F8, C4F6, CHF3, CH2F2, CH3F, NF3, NH3, CO2, SO2, CO, N2, NO2, N2O, H2, among others.

Valves 532 control the flow of the process gases from the process gas sources 524, 526, 528, 530 from the gas panel 520 and are managed by a controller 534. The flow of the gases supplied to the chamber body 505 from the gas panel 520 may include combinations of the gases.

The first end wall 514 may include a nozzle 536, wherein the nozzle 536 has one or more ports for introducing the process gases from the process sources 524, 526, 528, 530 of the gas panel 520 into the chamber volume 504. After the process gases are introduced into the plasma processing chamber 500, the gases are energized to form plasma. An antenna 538, such as one or more inductor coils, may be provided adjacent to the plasma processing chamber 500. An antenna power supply 541 may power the antenna 538 through a match circuit 542 to inductively couple energy, such as RF energy, to the process gas to maintain a plasma formed from the process gas in the chamber volume 504 of the plasma processing chamber 500. Alternatively, or in addition to the antenna power supply 541, process electrodes below the substrate W and/or above the substrate W may be used to capacitively couple RF power to the process gases to maintain the plasma within the chamber volume 504. The operation of the antenna power supply 541 may be controlled by a controller, such as controller 534, that also controls the operation of other components in the plasma processing chamber 500.

A platen or substrate support pedestal 544 is disposed below/adjacent the second end wall 515 to support the substrate W during processing. The substrate support pedestal 544 may include an electrostatic chuck (ESC) 546 for holding the substrate W during processing, wherein the ESC 546 uses the electrostatic attraction to hold the substrate W to the substrate support pedestal 544. The ESC 546 may be powered by a pulsed DC power supply 548 integrated with a match circuit 150. In some embodiments, the ESC 546 may be further powered by a secondary, RF power supply. The ESC 546 comprises an electrode 552 embedded within a dielectric body. The electrode 552 is coupled to the DC power supply 548 and provides a bias which attracts plasma ions, formed by the process gases in the chamber volume 504, to the ESC 546 and substrate W positioned thereon. The DC power supply 548 may cycle on and off, or pulse, during processing of the substrate W. In some embodiments, the ESC 546 may have an isolator (not shown) for the purpose of making the sidewall of the ESC 546 less attractive to the plasma to prolong the maintenance life cycle of the ESC 546.

In some embodiments, the electrode 552 may be coupled to a power source 558. The power source 558 provides a chucking voltage of about 166 volts to about 1660 volts to the electrode 552. The power source 558 may also include a system controller for controlling the operation of the electrode 552 by directing a DC current to the electrode 552 for chucking and de-chucking the substrate W.

The ESC 546 may include one or more temperature controllers disposed therein and connected to a power source (not shown), for heating or cooling the substrate. For example, a cooling base 560 supporting the ESC 546 may include conduits for circulating a heat transfer fluid to maintain a temperature of the ESC 546 and substrate W disposed thereon. The ESC 546 is configured to perform in the temperature range required by the thermal budget of the device being fabricated on the substrate W. For example, the ESC 546 may be configured to maintain the substrate W at a temperature of about 25 degrees Celsius to about 500 degrees Celsius for certain embodiments.

A shield or cover ring 562 is disposed on the ESC 546 and along the periphery of the substrate support pedestal 544. The cover ring 562 is configured to confine etching gases to a desired portion of the exposed top surface of the substrate W, while shielding the top surface of the substrate support pedestal 544 from the plasma environment inside the plasma processing chamber 500. In some embodiments, the cover ring 562 may be powered by one or more power sources, such as the power source 558. Lift pins (not shown) may be selectively moved through the substrate support pedestal 544 to lift the substrate W above the substrate support pedestal 544 to facilitate access to the substrate W by a transfer robot (not shown) or other suitable transfer mechanism.

The controller 534 may be utilized to control the process sequence, regulating the gas flows from the gas panel 520 into the plasma processing chamber 500 and other process parameters. Software routines, when executed by the controller 534, transform the controller 534 into a specific purpose computer (controller) that controls the plasma processing chamber 500 such that the processes are performed in accordance with the present disclosure. The software routines may also be stored and/or executed by a second controller (not shown) that is collocated with the plasma processing chamber 500.

Adjacent the substrate W may be an extraction assembly 555. As will be described in greater detail herein, the extraction assembly 555 may include optics having a plurality of apertures that allow for angled extraction of an ion beam, which is directed to the substrate W. The optics may be biased at an extraction plate voltage, such as the extraction voltage or a different voltage through the use of an extraction plate power source/supply 595. In some embodiments, this extraction plate power supply 595 may be used to provide the extraction voltage to the plasma processing chamber 500. In other embodiments, the extraction plate power supply 595 may only be in communication with the optics. Further, although one extraction plate power supply 595 is illustrated, it is understood that multiple extraction plate power supplies may be used in any embodiment. Still furthermore, an extraction plate of the optics may be grounded while the substrate W is negatively biased. Thus, in certain embodiments, the extraction plate voltage may be equal to the extraction voltage. In other embodiments, the extraction plate voltage may be different than the extraction voltage. For example, in the case of a positive extraction voltage, the extraction plate voltage may be less positive than the extraction voltage.

In some embodiments, the extraction plate power supply 595 may be referenced to ground, the extraction voltage, or to the substrate W. If referenced to the extraction voltage, the extraction plate power supply 595 may supply a non-positive voltage, such as ground or a negative voltage. If the extraction plate power supply 595 is referenced to the substrate W, the extraction plate power supply 595 may supply a positive voltage. Embodiments are not limited in this context.

In some embodiments, the first end wall 514 may further include a window 517 that facilitates optical process monitoring. In one implementation, the window 517 is comprised of quartz or other suitable material that is transmissive to a signal utilized by an optical monitoring system 521 mounted outside the plasma processing chamber 500. In other embodiments, the optical monitoring system 521 may alternatively, or additionally, be positioned adjacent the substrate W, external to the chamber body 505.

The optical monitoring system 521 is positioned to view at least one of the interior chamber volume 504 and/or the substrate W and the extraction assembly 555. In one embodiment, the optical monitoring system 521 is coupled to the first end wall 514 and facilitates an integrated etch and/or deposition process that uses optical metrology to provide information that enables process adjustment to compensate for incoming substrate pattern feature inconsistencies (such as thickness, and the like), and provide process state monitoring (such as plasma monitoring, temperature monitoring, and the like) as needed. One optical monitoring system that may be adapted to benefit from the disclosure is the EyeD® full-spectrum, interferometric metrology module, available from Applied Materials, Inc., of Santa Clara, CA.

For the sake of convenience and clarity, terms such as "top," "bottom," "upper," "lower," "vertical," "horizontal," "lateral," and "longitudinal" will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method comprising:
forming a plurality of mask lines over a stack of layers, wherein each of the plurality of mask lines includes a first sidewall and a second sidewall, and wherein a surface defect is present along the first sidewall or the second sidewall; and
removing the surface defect by delivering a reactive plasma beam to the plurality of mask lines at a non-zero angle relative to a perpendicular to a plane defined by an upper surface of the plurality of mask lines.

2. The method of claim 1, wherein delivering the reactive plasma beam to the plurality of mask lines further comprises scanning the reactive plasma beam in a first direction, wherein the first direction is parallel to a length axis of the plurality of mask lines.

3. The method of claim 2, wherein the surface defect is removed without increasing a width of a trench in a second direction, wherein the second direction is perpendicular to the first direction, and wherein the trench is defined by two adjacent mask lines of the plurality of mask lines.

4. The method of claim 1, wherein the plurality of mask lines is formed from a photoresist.

5. The method of claim 4, wherein the photoresist is a metal-oxide resist or a chemically amplified resist.

6. The method of claim 1, wherein the plurality of mask lines is formed from a first hardmask layer.

7. The method of claim 6, further comprising forming a recess in the stack of layers between two adjacent mask lines of the plurality of mask lines.

8. The method of claim 7, wherein the recess is formed through a second hardmask layer, and wherein the second hardmask layer is beneath the first hardmask layer.

9. The method of claim 1, wherein the stack of layers comprises an underlayer over a hardmask, and wherein the plurality of mask lines is directly atop the underlayer.

10. A method for minimizing surface defects present along a plurality of patterning features, the method comprising:
forming the plurality of patterning features over a stack of layers of a semiconductor device, wherein each of the plurality of patterning features includes a first sidewall and a second sidewall connected by an upper surface, and wherein a surface defect is present along at least one of the first sidewall and the second sidewall; and
removing the surface defect by delivering a reactive plasma beam to the plurality of patterning features at a non-zero angle relative to a perpendicular to a plane defined by the upper surface.

11. The method of claim 10, wherein delivering the reactive plasma beam to the plurality of patterning features further comprises scanning the reactive plasma beam in a first direction, wherein the first direction is parallel to a length axis of the plurality of patterning features.

12. The method of claim 11, wherein the surface defect is a plurality of protrusions, wherein the surface defect is removed without increasing a width of a trench between two adjacent patterning features of the plurality of patterning features, and wherein the width of the trench extends in a second direction, perpendicular to the first direction.

13. The method of claim 10, wherein the plurality of patterning features is formed from a metal-oxide resist (MOR) or from a chemically amplified resist (CAR).

14. The method of claim 10, wherein the plurality of patterning features is formed from a first hardmask layer.

15. The method of claim 14, further comprising forming a recess between two adjacent patterning features of the plurality of patterning features using the reactive plasma beam, wherein the recess is formed through a second hardmask layer, wherein the second hardmask layer is beneath the first hardmask layer.

16. The method of claim 10, wherein the stack of layers comprises an underlayer over a hardmask, wherein the plurality of patterning features is directly atop the underlayer.

17. A processing apparatus, comprising:
a chamber operable to contain a plasma within a chamber volume, the chamber defined by a plurality of sidewalls;
a plate assembly proximate the chamber, wherein ions are extracted through a plurality of apertures of the plate assembly and delivered to a semiconductor device as a reactive plasma beam oriented at a non-zero angle relative to a perpendicular extending from an upper surface of a stack of layers of the semiconductor device, and wherein the ions are operable to remove a surface defect present along a sidewall of a plurality of patterning lines formed over the stack of layers of the semiconductor device.

18. The processing apparatus of claim 17, wherein the reactive plasma beam is scanned in a first direction, and wherein the first direction is parallel to a length axis of the plurality of patterning lines.

19. The processing apparatus of claim 18, wherein the surface defect is a plurality of protrusions, wherein the surface defect is removed without increasing a width of a trench between two adjacent patterning lines of the plurality of patterning lines, and wherein the width of the trench extends in a second direction, perpendicular to the first direction.

20. The processing apparatus of claim 17, wherein the ions are further operable to form a recess between two adjacent patterning lines of the plurality of patterning lines using the reactive plasma beam, wherein the recess is formed through a second hardmask layer, wherein the second hardmask layer is beneath the hardmask layer.
